(19) United States
(12) Patent Application Publication
(10) Pub. No.: US 2009/0151985 A1
(43) Pub. Date: Jun. 18, 2009

(54) METHOD OF DICING A CIRCUIT BOARD SHEET AND PACKAGE CIRCUIT BOARD

(75) Inventor: Kishio YOKOUCHI, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 12/189,402

(22) Filed: Aug. 11, 2008

(30) Foreign Application Priority Data
Dec. 12, 2007 (JP) 2007-320784

(51) Int. Cl. H05K 1/00; H05K 3/00

(52) U.S. Cl. 174/250; 29/846

(57) ABSTRACT

When package circuit boards are formed by dicing a circuit board sheet with a core substrate that conducts electricity, conductive material is not exposed from the outer side surfaces of the package circuit boards, thereby preventing electrical shorting of the package circuit boards. A method of dicing a circuit board sheet includes: a step of forming a circuit board sheet by forming a core portion that includes a conductive material and providing a wiring layer on the surface of the core portion; a step of forming concave channels in a thickness direction of the circuit board sheet from one surface of the circuit board sheet so as to pass through at least the core portion; a step of forming an insulating cover layer on a surface of the wiring layer and inside the concave channels; and a step of dicing the circuit board sheet within widths of the concave channels with positions of the concave channels as dicing positions.

### BACKGROUND OF THE INVENTION

1. Field of the Invention

The present invention relates to a method of dicing a circuit board sheet and a package circuit board obtained by dicing a circuit board sheet, and in more detail to a favorable method of dicing a circuit board sheet where a wiring layer has been formed on a surface of a core portion that includes a conductive material and a package circuit board manufactured by such method.

2. Related Art

Among circuit boards used to mount semiconductor elements, circuit boards that use carbon fibers in the core portion have been provided to improve the strength of circuit boards and to make the thermal expansion coefficients of circuit boards match those of semiconductor elements. A circuit board that uses carbon fibers in the core portion has a low thermal expansion coefficient compared to a circuit board that uses a conventional glass epoxy substrate. By setting the thermal expansion coefficient of a circuit board so as to match the thermal expansion coefficient of a semiconductor element, it is possible to alleviate the thermal stress generated between the semiconductor element and the circuit board, which makes it possible to mount a large semiconductor element with a large number of pins.

During a conventional manufacturing process for circuit boards, after wiring layers and insulating layers have been formed on a large substrate to form a circuit board sheet equipped with predetermined wiring layers, the large circuit board sheet is diced to obtain individual circuit boards. The dicing process needs to achieve high precision for the external dimensions of the package circuit boards after dicing and to avoid producing burrs on the cut surfaces of the package circuit boards.
Patent Document 1

Japanese Laid-Open Patent Publication No. 2003-218287
Patent Document 2

Japanese Domestic Republication No. 2004/064467

### SUMMARY OF THE INVENTION

When a large circuit board sheet is diced into individual circuit boards using a dicing saw, the end surfaces (i.e., side surfaces) of the circuit boards become exposed at the cut surfaces and fragments produced by the dicing saw are left on the cut surfaces of the circuit board.

When a circuit board sheet that uses carbon fibers or metal fibers in the core portion (or prepregs) is used, the carbon fibers or metal fibers that conduct electricity will become exposed at the cut surfaces of the diced package circuit boards. That is, fragments of carbon fibers or metal fibers that are conductive will be left on the cut surfaces. This results in the problem of shorting occurring for the package circuit boards.

Carbon fibers have a high mechanical strength but are brittle, and therefore when a circuit board sheet is cut, there is a further problem in that carbon fibers can fall off the side surfaces of an individual circuit board and such carbon fibers (or carbon powder) can pollute an electronic device.

It is an object of the present invention to provide a method of dicing a circuit board sheet which, when forming package circuit boards by dicing a circuit board sheet including a conductive core substrate, does not expose conductive material from the outer surfaces of the package circuit boards and can therefore prevent electrical shorting by the package circuit boards, and to also provide a package circuit board.

A method of dicing a circuit board sheet according to the present invention includes: a step of forming a circuit board sheet by forming a core portion that includes a conductive material and providing a wiring layer on the surface of the core portion; a step of forming concave channels in a thickness direction of the circuit board sheet from one surface of the circuit board sheet so as to pass through at least the core portion; a step of forming an insulating cover layer on a surface of the wiring layer and inside the concave channels; and a step of dicing the circuit board sheet within widths of the concave channels with positions of the concave channels as dicing positions.

In the step of forming the insulating cover layer, the insulating cover layer may be formed so that a surface height of the insulating cover layer is lower at the positions of the concave channels than at parts where the wiring layer is formed. This is favorable since it becomes possible to clearly know the dicing positions even after the insulating cover layer has been formed on the surface of the circuit board sheet.

Alternatively, in the step of forming the insulating cover layer, the insulating cover layer may be formed so that a surface height of the insulating cover layer is uniform across the entire circuit board sheet including the positions of the concave channels at least above the core portion. This is favorable since it becomes possible to easily form the insulating cover layer on the wiring layer and the concave channels.

Also, in the step of forming the circuit board sheet, the core portion may be formed by laminating prepregs that include one of carbon fibers and metal fibers. In this way, by producing the core portion with a laminated structure, it is possible to provide the core portion with anisotropic properties and thereby satisfy demand for higher mechanical strength.

A package circuit board according to the present invention includes: a core portion including a material that conducts electricity; and a wiring layer that is formed on a surface of the core portion, wherein outer side surfaces of the package circuit board are covered by an insulating cover layer.

Here, the insulating cover layer may be formed so as to cover entire outer side surfaces of the package circuit board in a thickness direction thereof. This is favorable since it becomes possible to produce a state where the outer side surfaces (i.e., dicing surfaces) of the package circuit board are reliably covered with an insulator.

Alternatively, the insulating cover layer may be formed so as to cover at least side surfaces of the core portion out of the outer side surfaces of the package circuit board. To achieve this construction, it is necessary to form the insulating cover layer so that a surface height of the insulating cover layer is lower at positions where the circuit board sheet will be diced (i.e., the positions of the concave channels) than at other parts of the circuit board sheet. This is favorable since it is easy to check the dicing positions when dicing the circuit board sheet.

One of a metal material and a carbon material may be used as the material of the core portion. By doing so, it is possible to provide a package circuit board with superior mechanical characteristics and/or a package circuit board with superior heat dissipation characteristics.

According to the method of dicing a circuit board sheet according to the present invention and a package circuit board manufactured according to such method, no conductive fragments will be produced even when dicing a circuit board sheet that uses a conductive core portion. Accordingly, it is possible to provide a highly reliable package circuit board that is easy to dice from a circuit board sheet. Also, since the outer side surfaces of the package circuit board are covered by the insulating cover layer, the outer form of the package circuit board is determined by the insulating cover layer, and therefore it is possible to improve the precision of the outer dimensions of the package circuit board. In addition, since the outer form of the package circuit board is covered by the insulating cover layer, it is possible to provide a package circuit board that is highly reliable due to a conductive material included in the core portion, or a core portion that is itself conductive, not being exposed.

### BRIEF DESCRIPTION OF THE DRAWINGS

FIGS. 1A to 1D are cross-sectional views showing the procedure of a dicing process for a circuit board sheet according to a first embodiment of the present invention;

FIG. 2 is a cross-sectional view of a package circuit board produced by dicing the circuit board sheet shown in FIG. 1;

FIGS. 3A to 3D are cross-sectional views showing the procedure of a dicing process for a circuit board sheet according to a second embodiment of the present invention;

FIG. 4 is a cross-sectional view of a package circuit board produced by dicing the circuit board sheet shown in FIG. 3; and

FIGS. 5A and 5B are cross-sectional views of examples of other embodiments of a package circuit board.

### DESCRIPTION OF THE PREFERRED EMBODIMENTS

### First Embodiment

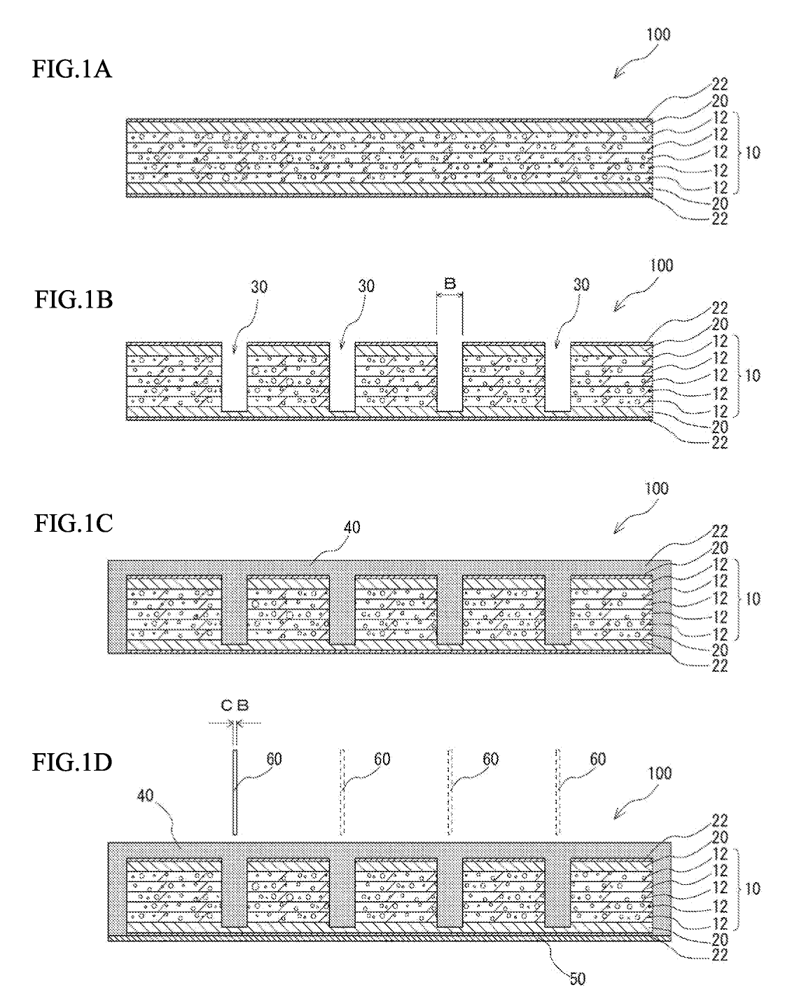

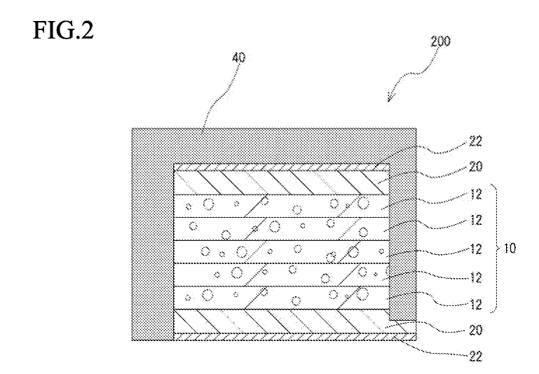

Preferred embodiments of a method of dicing a circuit board sheet according to the present invention will now be described with reference to the attached drawings. FIGS. 1A to 1D are cross-sectional views showing the procedure of a dicing process carried out on a circuit board sheet according to a first embodiment of the present invention. FIG. 2 is a cross-sectional view of a package circuit board produced by dicing the circuit board sheet shown in FIGS. 1A to 1D. Note that although entire wiring layers 20 and insulating layers 22 are shown with diagonal shading in the drawings referred to by the present specification for ease of understanding the present invention, wiring patterns or insulating films are not formed at all of the shaded parts.

In the present specification, a large laminated circuit board before dicing is referred to as a “circuit board sheet” and the laminated circuit boards produced by dicing such circuit board sheet are referred to as “package circuit boards”.

Note that the present specification describes a circuit board sheet with a core portion 10 formed by laminating a plurality of prepregs 12, which have been formed by impregnating carbon fibers with resin, through the application of heat and pressure.

As shown in FIG. 1A, the core portion 10 is constructed by stacking prepregs 12, which have been produced by impregnating carbon fibers with a composite resin such as epoxy resin, in the thickness direction and applying heat and pressure to laminate the prepregs 12.

After the core portion 10 has been formed, the wiring layers 20 are formed on both surfaces of the core portion 10. The wiring layers 20 are formed by an arbitrary method such as laminating wiring pattern films via the prepregs 12 or a build-up method. FIG. 1A shows a state where a large circuit board sheet 100 has been formed by forming wiring layers 20 on both surfaces of the core portion 10. On the illustrated circuit board sheet 100, the surfaces of the wiring layers 20 form the insulating layers 22.

After the circuit board sheet 100 has been formed, as shown in FIG. 1B, concaves or concave channels 30 are formed in the thickness direction of the circuit board sheet 100 from the insulating layer 22 on the upper surface side using a dicing blade at dicing positions where the circuit board sheet 100 will be diced into package circuit boards 200. Although not shown, it is preferable to provide a dicing blade protecting member such as dicing tape on the lower surface side of the circuit board sheet 100 when forming the concave channels 30. The concave channels 30 are formed from the insulating layer 22 on the upper surface side so as to reach a position that is deeper than (i.e., beyond) at least the core portion 10 (i.e., up to the height of a lower surface of the lowest prepreg 12). When doing so, care is taken so that the circuit board sheet 100 is not diced by the concave channels 30.

When forming the concave channels 30, it should be obvious that the depth of the concave channels 30 should be adjusted so that the circuit board sheet 100 does not become diced, and in addition sufficient thickness should be provided from the inner base surfaces of the concave channels 30 to the lower surface of the circuit board sheet 100 so that the circuit board sheet 100 does not break up at the positions of the concave channels 30 due to shock applied when the circuit board sheet 100 is conveyed following the formation of the concave channels 30.

After the concave channels 30 have been formed in the upper surface of the circuit board sheet 100, as shown in FIG. 1C, an insulating cover layer 40 composed of an insulating protective material such as a solder resist is formed on the upper surface and the side surfaces of the circuit board sheet 100 and inside the concave channels 30. The insulating cover layer 40 can be formed so as to cover the circuit board sheet 100 by a method that bonds a B-stage insulating film by thermal compression bonding or by a method that prints insulating paste.

In the present embodiment, the upper surface of the insulating cover layer 40 is formed flat across the entire surface of the circuit board sheet 100 regardless of the presence of the concave channels 30. The insulating cover layer 40 is also formed on the outermost end surfaces of the circuit board sheet 100.

After the insulating cover layer 40 has been formed, a dicing protective material 50 such as a die attach film is stuck onto the lower surface of the circuit board sheet 100. Next, a dicing blade 60 with a cutting width that is narrower than the gap between the inner walls (i.e., the channel width) B of the concave channels 30 is used to dice the circuit board sheet 100 with the concave channels 30 formed in the circuit board sheet 100 as the dicing positions. By dicing the circuit board sheet 100, package circuit boards 200 such as that shown in FIG. 2 are obtained.

Note that to expose connection pads and the like for connecting a semiconductor chip on the surface of the individual package circuit boards 200, it is possible to attach a photosensitive insulating film that will become the insulating cover layer 40 to the surface of the circuit board sheet 100 and then expose and develop the insulating cover layer 40 to remove the insulating material at predetermined positions.

On the package circuit board 200 shown in FIG. 2, at the outer surfaces where the concave channels 30 were formed, cut surfaces produced by the dicing blade 60 are exposed across the entire thickness of the package circuit board 200. With the package circuit board 200, surfaces where the insulating cover layer 40 was cut during dicing become exposed at the outer surfaces, so that the side surfaces of the core portion 10 are completely sealed by the insulating cover layer 40.

Accordingly, it is possible to reliably prevent the carbon fibers included in the core portion 10 from becoming exposed at the side surfaces of the package circuit board 200 and to reliably avoid the carbon fibers coming off to the outside. Also, when the circuit board sheet 100 is diced, since the dicing blade does not touch the core portion 10, no carbon fibers from the core portion 10 become mixed in the fragments produced by dicing. For this reason also, electrical shorting of the package circuit board 200 can be avoided.

### Second Embodiment

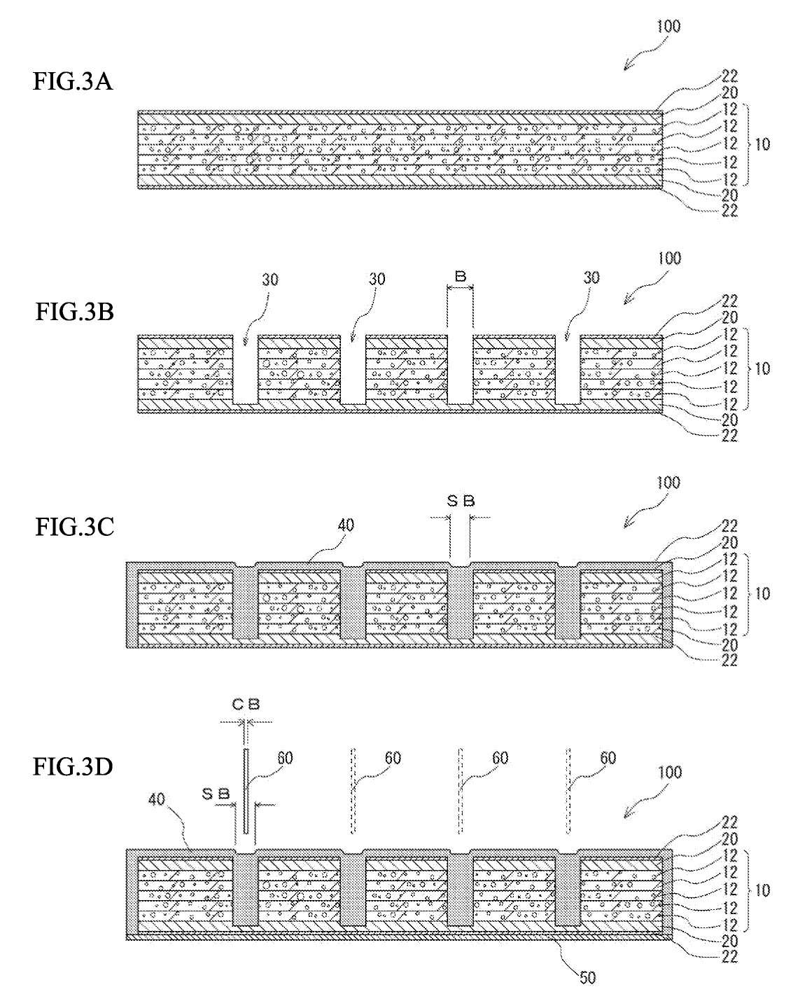

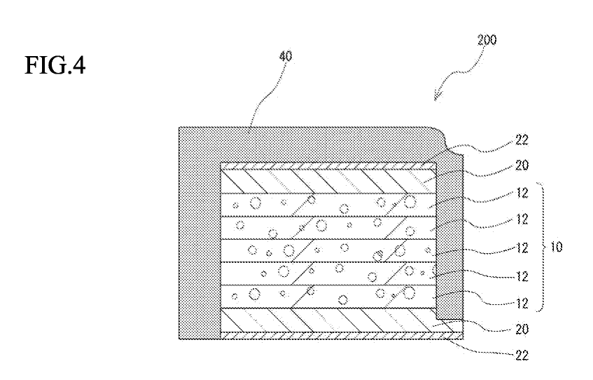

FIGS. 3A to 3D are cross-sectional views showing the procedure of a dicing process for a circuit board sheet according to a second embodiment. FIG. 4 is a cross-sectional view of a package circuit board produced by dicing the circuit board sheet shown in FIGS. 3A to 3D.

Since the constructions of the prepregs 12, the wiring layers 20, and the insulating layers 22 in this second embodiment are the same as the constructions in the first embodiment, detailed description thereof is omitted here.

First, as shown in FIG. 3A, the core portion 10 is constructed by laminating the prepregs 12 that include carbon fibers. By carrying out a build-up method or the like on both surfaces of the core portion 10 to form the wiring layers 20, the circuit board sheet 100 is formed. After the circuit board sheet 100 has been formed, as shown in FIG. 3B, the concave channels 30 are formed by a dicing blade at positions that will be used as the dicing positions of the circuit board sheet 100. The processes up to this point are the same as in the first embodiment.

Next, as shown in FIG. 3C, the insulating cover layer 40 that is composed of an insulating protective material such as a solder resist is formed on the side surfaces of the circuit board sheet 100 and inside the concave channels 30. The circuit board sheet 100 according to the present embodiment is characterized by the height of the insulating cover layer 40 at the concave channel 30 parts being formed lower than the height of the surface of the insulating cover layer 40 at positions where the wiring layer 20 is formed.

In more detail, as shown in FIG. 3D, the surface height of the insulating cover layer 40 in the present embodiment is set so that the height is uniform across the entire circuit board sheet 100 at positions above the core portion 10. On the other hand, in each range SB with the width of the concave channels 30, the surface height of the insulating cover layer 40 is lower than the height of the insulating cover layer 40 above the core portion 10 in keeping with the form of the concave channels 30. In the insulating cover layer 40, the parts (i.e., the parts with the width SB) where the surface height is lower than the other parts should preferably be wider than the cutting width CB of the dicing blade 60 used when dicing the circuit board sheet 100. That is, the channel width B of the concave channels 30, the width SB of the parts where the surface height of the insulating cover layer 40 is lower, and the cutting width CB of the dicing blade 60 are set so that CB<SB<B.

In any case, it is favorable for the surface of the insulating cover layer 40 to be depressed at the positions of the concave channels 30 where the circuit board sheet 100 will be diced since this makes it possible to clearly know the dicing positions even after the concave channels 30 have been filled with the insulating cover layer 40. Note that before the circuit board sheet 100 is diced at the positions of the concave channels 30, a dicing protective material 50 such as a die attach film is stuck onto the lower surface of the circuit board sheet 100.

The package circuit boards 200 obtained in this way have the construction shown in FIG. 4. On such package circuit boards 200 also, cut surfaces of the insulating cover layer 40 that was cut during dicing become exposed at the outer side surfaces, so that the side surfaces of the core portion 10 are completely sealed by the insulating cover layer 40. Accordingly, it is possible to reliably prevent the carbon fibers included in the core portion 10 from becoming exposed at the side surfaces of the package circuit board 200 and to reliably avoid the carbon fibers coming off to the outside. Also, when the circuit board sheet 100 is diced, since the dicing blade does not touch the core portion 10, no carbon fibers from the core portion 10 become mixed in the fragments produced by dicing. For this reason also, in the same way as in the first embodiment, electrical shorting of the package circuit board 200 can be avoided.

Although the circuit board sheet 100 and the package circuit boards 200 produced by dicing the circuit board sheet 100 according to embodiments of the invention have been described in detail, it should be obvious that the present invention is not limited to the embodiments described above. For example, although the dicing blade 60 is used when forming the concave channels 30 in the circuit board sheet 100 or when carrying out dicing on the circuit board sheet 100 according to the above embodiments, it is also possible to use a drill such as a router, a laser beam, or the like in place of the dicing blade 60.

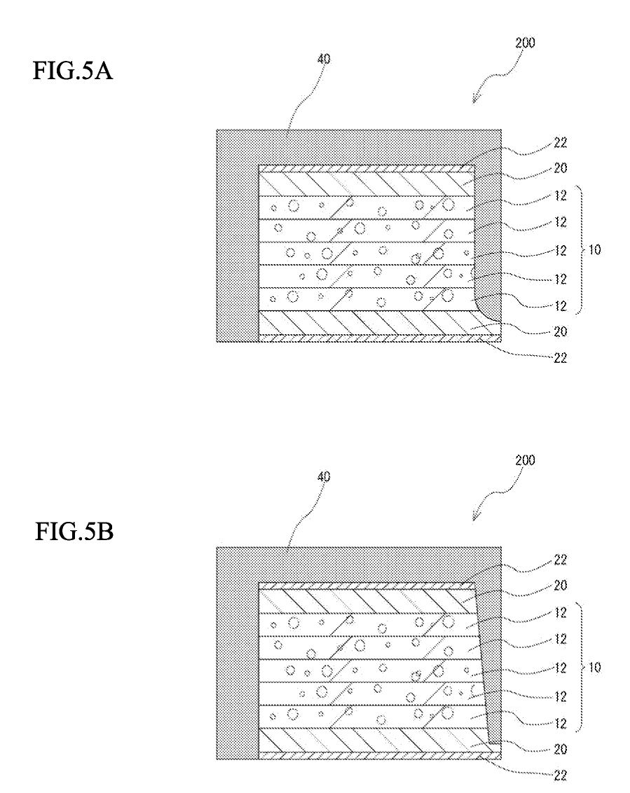

Although an aspect where the cross-sectional form of the concave channels 30 is rectangular has been described in the embodiments described above, it is also possible to form the concave channels 30 so as to be substantially U-shaped or inversely trapezoidal in cross section. FIGS. 5A and 5B show package circuit boards 200 that are obtained by forming the concave channels 30 with such shapes, forming the insulating cover layer 40 on the upper surface and side surfaces of the circuit board sheet 100, and then dicing the circuit board sheet 100 inside the concave parts (i.e., at the positions of the concave channels 30) in the upper surface of the insulating cover layer 40.

FIG. 5A shows a package circuit board 200 obtained by dicing the circuit board sheet 100 where the concave channels 30 have been formed so as to be substantially U-shaped in cross section, while FIG. 5B shows a package circuit board 200 obtained by dicing the circuit board sheet 100 where the concave channels 30 have been formed so as to be inversely trapezoidal in cross section.

When dicing the circuit board sheet 100 according to the second embodiment, although the circuit board sheet 100 is cut using the dicing blade 60 with a cutting width CB that is narrower than the upper surface width SB of the insulating cover layer 40 formed at a lower position inside the concave channels 30 than a part where the lower wiring layer 20 is formed, it is also possible for the dicing blade 60 to not satisfy such condition regarding the cutting width CB. However, the cutting width CB of the dicing blade 60 needs to be narrower than the width B between the inner walls of the concave channels 30.

Also, although the above embodiments describe an example where the circuit board sheet 100 is formed using the core portion 10 made by laminating a plurality of prepregs 12 where carbon fibers are impregnated with resin such as epoxy resin, it is also possible to form the core portion 10 using prepregs 12 where metal fibers are mixed into carbon fibers and to mix filler such as glass filler into the prepregs 12. In addition, it should be obvious that it is also possible to apply the constructions described in the above embodiments to a circuit board sheet 100 formed using a metal plate as one of the prepregs 12.

When a metal plate is used as part of the core portion 10, there is the advantage that it is possible to improve the heat dissipation performance of the package circuit board 200.

Although the package circuit board 200 described above is formed so that part of the cut surface of the lower wiring layer 20 is not covered by the insulating cover layer 40 and is exposed, it should be obvious that when at least one of the thickness and strength of an insulating layer 22 is sufficient, it is possible to set the base positions of the concave channels 30 inside such insulating layer 22. Such construction is favorable in that it is possible to eliminate exposed parts of the lower wiring layer 20 (i.e., parts not covered with the insulating cover layer 40) of the package circuit board 200.

What is claimed is:

1. A method of dicing a circuit board sheet comprising:
a step of forming a circuit board sheet by forming a core portion that includes a conductive material and providing a wiring layer on the surface of the core portion;
a step of forming concave channels in a thickness direction of the circuit board sheet from one surface of the circuit board sheet so as to pass through at least the core portion;
a step of forming an insulating cover layer on a surface of the wiring layer and inside the concave channels; and
a step of dicing the circuit board sheet within widths of the concave channels with positions of the concave channels as dicing positions.

2. A method of dicing a circuit board sheet according to claim 1,
wherein in the step of forming the insulating cover layer, the insulating cover layer is formed so that a surface height of the insulating cover layer is lower at the positions of the concave channels than at parts where the wiring layer is formed.

3. A method of dicing a circuit board sheet according to claim 1,
wherein in the step of forming the insulating cover layer, the insulating cover layer is formed so that a surface height of the insulating cover layer is uniform across the entire circuit board sheet including the positions of the concave channels at least above the core portion.

4. A method of dicing a circuit board sheet according to claim 1,
wherein in the step of forming the circuit board sheet, the core portion is formed by laminating prepregs that include one of carbon fibers and metal fibers.

5. A package circuit board, comprising:
a core portion including a material that conducts electricity; and
a wiring layer that is formed on a surface of the core portion,
wherein outer side surfaces of the package circuit board are covered by an insulating cover layer.

6. A package circuit board according to claim 5,
wherein the insulating cover layer is formed so as to cover entire outer side surfaces of the package circuit board in a thickness direction thereof.

7. A package circuit board according to claim 5,
wherein the insulating cover layer is formed so as to cover at least side surfaces of the core portion out of the outer side surfaces of the package circuit board.

8. A package circuit board, comprising:
a core portion including a material that conducts electricity; and
a wiring layer that is formed on a surface of the core portion,
wherein the core portion is made of one of a metal material and a carbon material, and
outer side surfaces of the package circuit board are covered by an insulating cover layer.

9. A package circuit board according to claim 8,
wherein the insulating cover layer is formed so as to cover entire outer side surfaces of the package circuit board in a thickness direction thereof.

10. A package circuit board according to claim 8,
wherein the insulating cover layer is formed so as to cover at least side surfaces of the core portion on the outer side surfaces of the package circuit board.
